(19) United States
(12) Patent Application Publication
(10) Pub. No.: US 2023/0040840 A1
(43) Pub. Date: Feb. 9, 2023

(54) METHOD FOR PRODUCING CONDUCTOR, CONDUCTOR PRODUCING APPARATUS, AND STRUCTURE

(71) Applicants: Shun GOTO, Tokyo (JP); Hiromichi KURIYAMA, Kanagawa (JP); Keigo TAKAUJI, Kanagawa (JP); Miku OHKIMOTO, Kanagawa (JP); Muxin LI, Kanagawa (JP)

(72) Inventors: Shun GOTO, Tokyo (JP); Hiromichi KURIYAMA, Kanagawa (JP); Keigo TAKAUJI, Kanagawa (JP); Miku OHKIMOTO, Kanagawa (JP); Muxin LI, Kanagawa (JP)

(21) Appl. No.: 17/868,785

(22) Filed: Jul. 20, 2022

(30) Foreign Application Priority Data
Jul. 26, 2021 (JP) 2021-121179

(51) Int. Cl. C08J 7/044; C09D 4/00; C08J 7/04; H05K 1/09

(52) U.S. Cl. CPC C08J 7/044; C09D 4/00; C08J 7/0423; H05K 1/09; C08J 2323/06; C08J 2323/12; C08J 2367/02; C08J 2435/02; H05K 3/10

(57) ABSTRACT

Embodiments of the present invention provide a method for producing a conductor. The method includes: applying a resin forming composition containing a polymerizable compound and a solvent on a substrate; polymerizing the polymerizable compound in the applied resin forming composition to form a resin structure that is porous on the substrate; and applying a conductor forming composition containing at least one selected from the group consisting of metal oxide particles and metal particles on the resin structure.

### CROSS-REFERENCE TO RELATED APPLICATIONS

This patent application is based on and claims priority pursuant to 35 U.S.C. § 119(a) to Japanese Patent Application No. 2021-121179, filed on Jul. 26, 2021, in the Japan Patent Office, the entire disclosure of which is incorporated by reference herein.

### BACKGROUND

### Technical Field

The present disclosure relates to a method for producing a conductor, a conductor producing apparatus, and a structure.

### Description of the Related Art

Currently, printed electronics technologies are actively studied, in which a conductor such as a metal is directly formed on a base plate using a printing process.

### SUMMARY

Embodiments of the present invention provide a method for producing a conductor. The method includes: applying a resin forming composition containing a polymerizable compound and a solvent on a substrate; polymerizing the polymerizable compound in the applied resin forming composition to form a resin structure that is porous on the substrate; and applying a conductor forming composition containing at least one selected from the group consisting of metal oxide particles and metal particles on the resin structure.

Embodiments of the present invention provide a conductor producing apparatus. The conductor producing apparatus includes: a resin forming composition applying device configured to apply a resin forming composition containing a polymerizable compound and a solvent on a substrate; a resin structure forming device configured to polymerize the polymerizable compound in the applied resin forming composition to form a resin structure that is porous on the substrate; and a conductor forming composition applying device configured to apply a conductor forming composition containing at least one selected from the group consisting of metal oxide particles and metal particles on the resin structure.

Embodiments of the present invention provide a structure. The structure includes: a substrate; a resin structure on the substrate, the resin structure being porous; and a conductor on the resin structure. The resin structure comprises an acrylic resin. The resin structure has a mixed region containing a material same as a material of the conductor within pores.

### BRIEF DESCRIPTION OF THE DRAWING

A more complete appreciation of the disclosure and many of the attendant advantages and features thereof can be readily obtained and understood from the following detailed description with reference to the accompanying drawing, wherein the drawing is a schematic diagram illustrating a conductor producing apparatus according to an embodiment of the present invention.

The accompanying drawing is intended to depict embodiments of the present disclosure and should not be interpreted to limit the scope thereof. The accompanying drawings are not to be considered as drawn to scale unless explicitly noted.

### DETAILED DESCRIPTION

In describing embodiments illustrated in the drawing, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

Referring now to the drawing, embodiments of the present disclosure are described below. As used herein, the singular forms “a,” “an,” and “the” are intended to include the plural forms as well, unless the context clearly indicates otherwise.

Embodiments of the present invention provide a method for producing a conductor. When forming a porous resin structure on a substrate and further forming a conductor on the resin structure by this method, the method can improve conductivity of the conductor and adhesiveness of the conductor to the resin structure.

An embodiment of the present invention will be explained below.

«Method for Producing Conductor»

The method for producing a conductor according to this embodiment includes: a resin forming composition applying process in which a resin forming composition containing a polymerizable compound and a solvent is applied on a substrate; a resin structure forming process in which the polymerizable compound is polymerized in the applied resin forming composition to form a porous resin structure layer (hereinafter, also referred to as “porous resin layer”) on the substrate; and a conductor forming composition applying process in which a conductor forming composition containing at least one selected from metal oxide particles and metal particles is applied on the resin structure layer. The method for producing the conductor according to this embodiment may also include other processes as necessary. For example, the method may include: a solvent removing process in which the solvent is removed from the resin structure layer, after the resin structure layer forming process and before the conductor forming composition applying process; a conductor forming process in which at least one selected from the metal oxide particles and the metal particles is selectively caused to generate heat to form a conductor including at least one sintered compact selected from the reduced metal oxide particles and the metal particles on the resin structure layer, after the conductor forming composition applying process; and the like.

<Resin Forming Composition Applying Process>

In the resin forming composition applying process, the resin forming composition containing the polymerizable compound and the solvent is applied on the substrate. Preferably, the applied resin forming composition is formed into the resin forming composition layer that is a liquid film of the resin forming composition on the substrate. The method for applying the resin forming composition is not particularly limited. Examples of the method may include various printing methods such as a spin coating method, a casting method, a micro-gravure coating method, a gravure coating method, a bar coating method, a roll coating method, a wire bar coating method, a dip coating method, a slit coating method, a capillary coating method, a spray coating method, a nozzle coating method, a gravure printing method, a screen printing method, a flexographic printing method, an offset printing method, a reverse printing method, and an inkjet printing method.

—Resin Forming Composition—

The resin forming composition is a liquid composition containing a polymerizable compound, a solvent, and, as necessary, other components such as a polymerization initiator. The resin forming composition forms the porous resin structure when cured, and forms the porous resin layer as a layered porous resin when applied on a substrate and cured.

In the present disclosure, meaning of the formation of the porous resin structure by the resin forming composition includes a meaning that at least some components (polymerizable compound and the like) in the resin forming composition are cured (polymerized) to form a porous resin structure but the remaining components (solvents and the like) in the resin forming composition are not cured to form no porous resin structure.

—Polymerizable Compound—

The polymerizable compound forms a resin by polymerization. When polymerized in the resin forming composition, the polymerizable compound forms a resin skeleton of the porous resin structure. Preferably, the polymerizable compound forms the resin by application of an active energy ray or the like (e.g. light irradiation, heating). Preferable examples of the resin may include an acrylate resin, a methacrylate resin, a urethane acrylate resin, a vinylester resin, an unsaturated polyester, an epoxy resin, an oxetane resin, a vinylether, and a resin utilizing an ene-thiol reaction. From the viewpoint of productivity, above all, an acrylate resin, a methacrylate resin, a urethane acrylate resin, and a vinylester resin are more preferable, because these resins can be easily formed using highly reactive radical polymerization. Each of these resins may be used alone or in combination of two or more types. Preferably, the resin constituting the porous resin is e.g. an acrylic resin.

The polymerizable compound has at least one polymerizable functional group, but it is preferable that the polymerizable compound have a plurality of polymerizable functional groups to form a resin having an intramolecular crosslinked structure. When the resin skeleton of the porous resin layer is formed from the resin having the intramolecular crosslinked structure, deformation of the porous resin layer during heating can be suppressed. For example, even if the porous resin layer is heated by heat generation of metal oxide particles or metal particles located inside or near the porous resin layer in the conductor forming process described below, deformation of the porous resin layer is suppressed by suppressing decomposition of the resin constituting the porous resin layer, thereby cracks of the conductor on the porous resin layer are suppressed, and as a result, conductivity of the conductor and adhesiveness of the conductor to the porous resin layer can be improved. The porous resin layer is formed from the resin having the intramolecular crosslinked structure, so that a solvent resistance can also be improved.

Preferably, the polymerizable compound has at least one radical polymerizable functional group. Examples of the polymerizable compound may include a monofunctional, bifunctional, trifunctional or higher radical polymerizable compound, a functional monomer, and a radical polymerizable oligomer. Above all, a bifunctional or higher radical polymerizable compound is preferable.

Examples of the monofunctional radical polymerizable compound may include 2-(2-ethoxyethoxy)ethyl acrylate, methoxy polyethylene glycol monoacrylate, methoxy polyethylene glycol monomethacrylate, phenoxy polyethylene glycol acrylate, 2-acryloyloxyethyl succinate, 2-ethylhexyl acrylate, 2-hydroxyethyl acrylate, 2-hydroxypropyl acrylate, tetrahydrofurfuryl acrylate, 2-ethylhexyl carbitol acrylate, 3-methoxybutyl acrylate, benzyl acrylate, cyclohexyl acrylate, isoamyl acrylate, isobutyl acrylate, methoxytriethylene glycol acrylate, phenoxytetraethylene glycol acrylate, cetyl acrylate, isostearyl acrylate, stearyl acrylate, and styrene monomer. Each of these monofunctional radical polymerizable compounds may be used alone or in combination of two or more types.

Examples of the bifunctional radical polymerizable compound may include 1,3-butanediol diacrylate, 1,4-butanediol diacrylate, 1,4-butanediol dimethacrylate, 1,6-hexanediol diacrylate, 1,6-hexanediol dimethacrylate, diethylene glycol diacrylate, polyethylene glycol diacrylate, neopentyl glycol diacrylate, EO-modified bisphenol A diacrylate, EO-modified bisphenol F diacrylate, neopentyl glycol diacrylate, and tricyclodecanedimethanol diacrylate. Each of these bifunctional radical polymerizable compounds may be used alone or in combination of two or more types.

Examples of the trifunctional or higher radical polymerizable compound may include trimethylolpropane triacrylate (TMPTA), trimethylolpropane trimethacrylate, EO-modified trimethylolpropane triacrylate, PO-modified trimethylolpropane triacrylate, caprolactone-modified trimethylolpropane triacrylate, HPA-modified trimethylolpropane trimethacrylate, pentaerythritol triacrylate, pentaerythritol tetraacrylate (PETTA), glycerol triacrylate, ECH-modified glycerol triacrylate, EO-modified glycerol triacrylate, PO-modified glycerol triacrylate, tris(acryloxyethyl)isocyanurate, dipentaerythritol hexaacrylate (DPHA), caprolactone-modified dipentaerythritol hexaacrylate, dipentaerythritol hydroxypentaacrylate, alkyl-modified dipentaerythritol pentaacrylate, alkyl-modified dipentaerythritol tetraacrylate, alkyl-modified dipentaerythritol triacrylate, dimethylolpropane tetraacrylate (DTMPTA), pentaerythritol ethoxytetraacrylate, EO-modified phosphoric triacrylate, and 2,2,5,5-tetrahydroxymethylcyclopentanone tetraacrylate. Each of these trifunctional radical polymerizable compounds may be used alone or in combination of two or more types.

A content of the polymerizable compound in the resin forming composition is preferably 5.0% by mass or more and 70.0% by mass or less, more preferably 10.0% by mass or more and 60.0% by mass or less, based on the total amount of the resin forming composition. A case in which the content of the polymerizable compound is 70.0% by mass or less is preferable because the resultant porous resin has several nanometers or less of pore size which is not too small, and the porous resin has an appropriate porosity. A case in which the content of the polymerizable compound is 5.0% by mass or more is preferable because a three-dimensional network structure is sufficiently formed in the resin to sufficiently form the porous structure, and there is a tendency that the strength of the resultant porous structure is also improved.

—Solvent—

The solvent (hereinafter, also referred to as “porogen”) is a liquid compatible with the polymerizable compound. Also, the solvent is a liquid that is incompatible with (phase-separated from) the polymer (resin) generated in the process of polymerizing the polymerizable compound in the resin forming composition. Because the resin forming composition contains the solvent, the polymerizable compound is polymerized in the resin forming composition to form the porous resin. It is preferable that the solvent is capable of dissolving a compound (polymerization initiator described later) that generates radicals or acids by light or heat. One type of solvent may be used alone, or two or more types of solvents may be used in combination. Note that the solvent is not polymerizable.

One type of the porogen alone or a combination of two or more types of the porogens has a boiling point of preferably 50° C. or higher and 250° C. or lower, more preferably 70° C. or higher and 200° C. or lower, at normal pressure. When the boiling point is 50° C. or higher, vaporization of the porogen is suppressed at around room temperature and the resin forming composition is easy to handle, so that the content of the porogen in the resin forming composition can be easily controlled. When the boiling point is 250° C. or lower, the time required for drying the porogen after polymerization is shortened, and the productivity is improved.

Examples of the porogen may include ethylene glycols such as diethylene glycol monomethyl ether, ethylene glycol monobutyl ether, ethylene glycol monoisopropyl ether, and dipropylene glycol monomethyl ether; γ-butyrolactone; esters such as propylene carbonate; and amides such as N,N-dimethylacetamide. Also, examples of the porogen may include liquids having a relatively large molecular weight, such as methyl tetradecanoate, methyl decanoate, methyl myristate, and tetradecane. Also, examples of the porogen may include liquids such as acetone, 2-ethylhexanol, and 1-bromonaphthalene.

Note that the liquids described above as examples do not always serve as a porogen. The porogen refers to a liquid that is compatible with the polymerizable compound as described above, and incompatible with (phase-separated from) the resultant polymer (resin) in the process of polymerizing the polymerizable compound in the resin forming composition. In other words, whether or not a liquid serves as a porogen depends on the relation between the polymerizable compound and the resultant polymer (resin formed by polymerization of the polymerizable compound).

The resin forming composition only needs to contain at least one type of porogen having the aforementioned specific relation with the polymerizable compound. Therefore, the range of selection of materials for preparing the resin forming composition is widened, and the resin forming composition is easy to design. As the range of selection of materials for preparing the resin forming composition is widened, the resin forming composition can provide a wide range of application in response to requirements for any characteristics of the resin forming composition other than the capability of forming a porous structure. For example, when the resin forming composition is discharged by an inkjet method, the resin forming composition is required to have discharge stability and the like as a required characteristic other than the capability of forming a porous structure. In this case, since the range of selection of materials is wide, the resin forming composition is easy to design.

Since the resin forming composition only needs to contain at least one type of porogen having the aforementioned specific relation with the polymerizable compound as described above, the resin forming composition may additionally contain a liquid (non-porogen liquid) that does not have the aforementioned specific relation with the polymerizable compound. The content of the liquid (non-porogen liquid) that does not have the aforementioned specific relation with the polymerizable compound is preferably 10.0% by mass or less, more preferably 5.0% by mass or less, even more preferably 3.0% by mass or less, particularly preferably 1.0% by mass or less, based on the total amount of the resin forming composition.

The case of not containing the non-porogen liquid also include: a case in which the content of the liquid (non-porogen liquid) that does not have the aforementioned specific relation with the polymerizable compound is completely zero; as well as a case in which the liquid (non-porogen liquid) that does not have the aforementioned specific relationship with the polymerizable compound is not aggressively used for producing the resin forming composition; or a case in which the liquid (non-porogen liquid) that does not have the aforementioned specific relation with the polymerizable compound cannot be detected when analyzing the resin forming composition using a known procedure based on common general knowledges.

A content of the porogen in the resin forming composition is preferably 30.0% by mass or more and 95.0% by mass or less, more preferably 40.0% by mass or more and 90.0% by mass or less, based on the total amount of the resin forming composition. It is preferable that the content of the porogen is 30.0% by mass or more, because a resultant porous body has a pore size of several nanometers or less which is not too small, and the porous body has an appropriate porosity. In addition, it is preferable that the content of the porogen is 95.0% by mass or less, because a three-dimensional network structure of the resin is sufficiently formed to form a sufficient porous structure and there is a tendency that the strength of the resultant porous structure is also improved.

—Polymerization-Induced Phase Separation—

The porous resin can be formed by polymerization-induced phase separation. The polymerization-induced phase separation refers to a state in which the porogen is compatible with the polymerizable compound but is incompatible with (phase-separated from) the polymer (resin) produced in the process of polymerizing the polymerizable compound. Among existing methods for obtaining a porous body by phase separation, use of the polymerization-induced phase separation method makes it possible to form a porous body having a network structure and a co-continuous structure in which pore portions and skeleton portions as two components constituting the porous resin are continuous with each other, and therefore the porous body is expected to have high chemical resistance and heat resistance. Also, as compared with other methods, the polymerization-induced phase separation has advantages of shorter process time and easier surface modification.

Next, a porous resin forming process using the polymerization-induced phase separation will be explained. The polymerizable compound undergoes a polymerization reaction upon light irradiation or the like to form a resin. During this process, the solubility of the growing resin in the porogen decreases to cause a phase separation between the resin and the porogen. Finally, the resin forms a porous structure in which the pores are filled with the porogen and the like.

This porous structure is dried to remove the porogen and the like, so that the skeleton portions of the porous resin structure remain. Thus, in order to form the porous resin having an appropriate porosity, the compatibility of the porogen with the polymerizable compound and the compatibility of the porogen with the resin formed by polymerization of the polymerizable compound are investigated.

The compatibility between the porogen and the polymerizable compound is determined as follows.

First, the resin forming composition is injected into a quartz cell, and a light (visible light) transmittance of the resin forming composition at a wavelength of 550 nm is measured while stirring the resin forming composition at 300 rpm using a stirrer.

In the present disclosure, when the light transmittance is 30% or higher, it is determined that the polymerizable compound and the porogen are in a compatible state, and when the light transmittance is lower than 30%, it is determined that the polymerizable compound and the porogen are in an incompatible state. Conditions for measuring the light transmittance are as described below.
Quartz cell: Special microcell with screw cap (trade name: M25-UV-2)
Transmittance measuring apparatus: USB 4000, manufactured by Ocean Optics, Inc.
Stirring speed: 300 rpm
Measurement wavelength: 550 nm
Reference: Light transmittance at a wavelength of 550 nm is measured and acquired with the quartz cell filled with air (transmittance: 100%)

The compatibility between the porogen and the resin formed by polymerization of the polymerizable compound is determined as follows.

First, resin fine particles are uniformly dispersed on a non-alkali glass base plate by spin coating to form a gap agent. Subsequently, the base plate to which the gap agent has been applied and another non-alkali glass base plate to which no gap agent has been applied are brought to bond to each other so as to sandwich the surface coated with the gap agent. Then, the resin forming composition is charged into the space between the bonded base plates by utilizing capillary phenomenon to prepare a “pre-ultraviolet (UV) irradiation haze measuring element”. Subsequently, the pre-UV irradiation haze measuring element is irradiated with UV to cure the resin forming composition. Finally, the peripheries of the base plates are sealed with a sealing agent to prepare a “haze measuring element”. Preparation conditions are described below.
Non-alkali glass base plate: OA-10G, manufactured by Nippon Electric Glass Co., Ltd., 40 mm, t=0.7 mm
Gap agent: resin fine particles MICROPEARL GS-L100, manufactured by Sekisui Chemical Company, Limited, average particle diameter=100
Spin coating conditions: dispersion droplet volume=150 μL, rotation speed=1000 rpm, rotation time=30 s
Amount of the charged resin forming composition: 160 μL
UV irradiation conditions: light source=UV-LED, light source wavelength=365 nm, irradiation intensity=30 mW/cm², irradiation time=20 s
Sealing agent: TB3035B (manufactured by ThreeBond Co., Ltd.)

Next, the haze values (cloudiness) are measured using the prepared pre-UV irradiation haze measuring element and the haze measuring element. The measured haze value of the pre-UV irradiation haze measuring element is defined as a reference (the haze value is 0). An increasing rate of the measured value (haze value) of the haze measuring element with respect to the measured value of the pre-UV irradiation haze measuring element is calculated. The haze value of the haze measuring element increases as the compatibility between the resin formed by polymerization of the polymerizable compound and the porogen decreases, and the haze value of the haze measuring element decreases as the compatibility increases. A higher haze value indicates that the resin formed by polymerization of the polymerizable compound is more likely to form a porous structure. In the present disclosure, when the haze increasing rate is 1.0% or higher, it is determined that the resin and the porogen are in an incompatible state, and when the haze increasing rate is lower than 1.0%, it is determined that the resin and the porogen are in a compatible state. An apparatus used for the measurement is as follows.
Haze meter: Haze meter NDH5000, manufactured by NIPPON DENSHOKU INDUSTRIES CO., LTD.

—Polymerization Initiator—

The polymerization initiator is a material capable of generating active species such as radicals and cations by energy such as light and heat to initiate polymerization of the polymerizable compound. As the polymerization initiator, a known radical polymerization initiator, a cationic polymerization initiator, a base generator, or the like can be used alone or in combination of two or more types. Particularly, it is preferable to use a photoradical polymerization initiator.

As the photoradical polymerization initiator,

a photoradical generator can be used. For example, it is preferable to use a photoradical polymerization initiator such as Michler's ketone and benzophenone known as trade name: IRGACURE or DAROCUR, and, as more specific compounds, benzophenone, acetophenone derivatives, for example, α-hydroxy- or α-aminoacetophenone, 4-aroyl-1,3-dioxolane, benzyl ketal, 2,2-diethoxyacetophenone, p-dimethylaminoacetophene, p-dimethylaminopropiophenone, benzophenone, 2-chlorobenzophenone, pp′-dichlorobenzophene, pp′-bis-diethylaminobenzophenone, Michler's ketone, benzyl, benzoin, benzyl dimethyl ketal, tetramethylthiuram monosulphide, thioxanthone, 2-chlorothioxanthone, 2-methylthioxanthone, azobisisobutyronitrile, benzoin peroxide, di-tert-butyl peroxide, 1-hydroxycyclohexylphenyl ketone, 2-hydroxy-2-methyl-1-phenyl-1-one, 1-(4-isopropylphenyl)-2-hydroxy-2-methylpropan-1-one, methylbenzoylformate, benzoin isopropyl ether, benzoin methyl ether, benzoin ethyl ether, benzoin ether, benzoin isobutyl ether, benzoin n-butyl ether, benzoin n-propyl, 1-hydroxy-cyclohexyl-phenyl-ketone, 2-benzyl-2-dimethylamino-1-(4-morpholinophenyl)-butanone-1,1-hydroxy-cyclohexyl-phenyl-ketone, 2,2-dimethoxy-1,2-diphenylethane-1-one, bis(η5-2,4-cyclopentadiene-1-yl)-bis(2,6-difluoro-3-(1H-pyrrol-1-yl)-phenyl) titanium, bis(2,4,6-trimethylbenzoyl)-phenylphosphine oxide, 2-methyl-1[4-(methylthio)phenyl]-2-morfolinopropan-1-one, 2-hydroxy-2-methyl-1-phenyl-propane-1-one (DAROCUR 1173), bis(2,6-dimethoxybenzoyl)-2,4,4-trimethyl-pentylphosphine oxide, 1-[4-(2-hydroxyethoxy)-phenyl]-2-hydroxy-2-methyl-1-propane-1-one monoacylphosphine oxide, bisacylphosphine oxide or titanocene, fluoresceine, anthraquinone, thioxanthone or xanthone, lophine dimer, trihalomethyl or dihalomethyl compounds, active ester compounds, organoboron compounds, or the like.

Also, the same function can be achieved with a resin forming composition obtained by combining a photoacid generator for generating acids through light irradiation and a polymerizable compound polymerizable in the presence of acids. When the resin forming composition is irradiated with light, the photoacid generator generates acids, and the acids functionally serve as catalysts for the reaction of the polymerizable compound. The generated acids diffuse within the resin forming composition. Acid diffusion and acid-catalyzed reactions can be accelerated by heating, and this reaction is not inhibited by oxygen unlike radical polymerization. The resultant resin also has superior adhesiveness compared to the radical polymerization system.

The polymerizable compound that is crosslinkable in the presence of acids can be used in combination with monomers having a cationically polymerizable vinyl bond: e.g. a compound having a cyclic ether group, such as an epoxy group, an oxetane group, and an oxolane group; an acrylic or vinyl compound having the aforementioned substituents on a side chain; a carbonate compound; a low molecular weight melamine compound; a vinyl ether or a carbazole; a styrene derivative; an alpha-methylstyrene derivative; a vinyl alcohol ester including an ester compound such as vinyl alcohol, and acryl or methacryl.

As the photoacid generator for generating acids through light irradiation, it is possible to use an onium salt, a diazonium salt, a quinonediazide compound, an organic halide, an aromatic sulfonate compound, a bisulfone compound, a sulfonyl compound, a sulfonate compound, a sulfonium compound, a sulfamide compound, an iodonium compound, a sulfonyldiazomethane compound, a mixture thereof, or the like.

Above all, it is desirable to use an onium salt as the photoacid generator. Examples of usable onium salts may include fluoroborate anions, hexafluoroantimonate anions, hexafluoroarsenate anions, trifluoromethanesulfonate anions, paratoluenesulfonate anions, as well as diazonium salts, phosphonium salts, and sulfonium salts, of which counter ions are paratoluenesulfonate anions. As the photoacid generator, a halogenated triazine compound can also be used.

Optionally, the photoacid generator may further contain a sensitizing dye. Examples of the sensitizing dye may include an acridine compound, a benzoflavin, a perylene, an anthracene, and a laser dye.

For achieving a sufficient curing speed, the content of the polymerization initiator is preferably 0.05% by mass or more and 10.0% by mass or less, more preferably 0.5% by mass or more and 5.0% by mass or less when the total mass of the polymerizable compound is 100.0% by mass.

—Others—

The resin forming composition according to the present disclosure may be a non-dispersible composition containing no dispersions (e.g. particulate matter) or a dispersible composition containing dispersions, but the non-dispersible composition is preferable. This is because the resin forming composition as a non-dispersible composition can be used for various application devices. For example, since the non-dispersible composition can also be stably used in inkjet systems where preservation of discharge stability is important, the non-dispersible composition is preferable. The phrase “resin forming composition contains no dispersions” means that the composition only needs to contain substantially no dispersions, for example, the content of the dispersions only needs to be less than or equal to the content where the influence of containing dispersions is not caused. Specifically, for example, the content of the dispersions is preferably 0.1% by mass or less based on the mass of the resin forming composition, and when measured using a known procedure based on common general knowledges, the content of the dispersions is more preferably a detection limit or lower.

—Substrate—

The substrate is a member on which the resin forming composition is applied. A material constituting the substrate is not limited. The material is preferably a material that does not generate heat by an internal heating method described later, and is preferably a resin. The characteristics of the substrate are not particularly limited. In the method for producing the conductor according to embodiments of the present invention, it is preferable that the substrate has low heat resistance from the viewpoint of increasing the resultant effect, considering that even a substrate having low heat resistance (in other words, substrate that is easily deformed by heated) can be applied, as described later.

As an example of the case in which the substrate has low heat resistance as a characteristic, a differential scanning calorimetry (DSC) on the substrate indicates an exothermic or endothermic peak at 300° C. or lower. An example of the measurement conditions for the differential scanning calorimetry (DSC) on the substrate is as follows.

First, a part of the substrate is cut out to prepare a test piece of about 5 mg, and the test piece is vacuum-dried at 150° C. for 24 hours to obtain a measurement sample. Subsequently, heat characteristics of the measurement sample are measured using a differential scanning calorimeter (DSC) (Q2000, manufactured by TA Instruments) under the following conditions.
Sample container: aluminum sample pan (with a lid)
Sample amount: 5 mg
Reference aluminum sample pan (empty container)
Atmosphere: nitrogen (flow rate 50 mL/min)
Start temperature: 25° C.
Temperature rising rate: 10° C./min
End temperature: 300° C.

As another example of the case in which the substrate has low heat resistance as a characteristic, the heat resistance of the substrate is lower than that of the porous resin. Specifically, when a differential scanning calorimetry (DSC) is performed on the substrate and the porous resin layer, the temperature at the exothermic or endothermic peak on the substrate is lower than the temperature at the endothermic peak on the porous resin layer e.g. by 20° C. or more, 30° C. or more, or the like. Thus, even if the substrate has low heat resistance, deformation of the substrate is suppressed because the substrate is integrated with a material that generates heat by the internal heating method described later via a porous resin layer having heat resistance higher than the substrate. Thereby, cracks on the conductor disposed on the porous resin layer are suppressed, and, as a result, the conductivity of the conductor and the adhesiveness of the conductor to the porous resin layer can be improved. The differential scanning calorimetry (DSC) on the porous resin is performed as described above, and the measurement conditions of the differential scanning calorimetry (DSC) on the porous resin layer are as follows.

First, a part of the porous resin layer is cut out to prepare a test piece of about 5 mg, and the test piece is vacuum-dried at 150° C. for 24 hours to obtain a measurement sample. Subsequently, heat characteristics of the measurement sample are measured using a differential scanning calorimeter (DSC) (Q2000, manufactured by TA Instruments) under the following conditions.
Sample container: aluminum sample pan (with a lid)
Sample amount: 5 mg
Reference aluminum sample pan (empty container)
Atmosphere: nitrogen (flow rate 50 mL/min)
Start temperature: 25° C.
Temperature rising rate: 10° C./min
End temperature: 300° C.

Examples of substrate materials having low heat resistance may include polypropylene, polyethylene, polystyrene, polyethylene terephthalate, thermoplastic polyurethane (TPU), polycarbonate, polyurethane, polytetrafluoroethylene, polybutadiene, polyolefin, poly-4-methylpentene, polyester, and polyethylene naphthalate. Above all, polyethylene, polypropylene, polyethylene terephthalate, and polyethylene naphthalate are preferable. The substrate may contain only one or a plurality of these materials.

—Method for Producing Resin Forming Composition—

Preferably, the resin forming composition is prepared through a process in which the polymerization initiator is dissolved in the polymerizable compound, a process in which the porogen and other components are further dissolved, a process in which the mixture is stirred to obtain a uniform solution, and the like.

—Physical Properties of Resin Forming Composition—

From the viewpoint of operability in applying the resin forming composition, a viscosity of the resin forming composition is preferably 1.0 mPa·s or higher and 150.0 mPa·s or lower, more preferably 1.0 mPa·s or higher and 30.0 mPa·s or lower, even more preferably 1.0 mPa·s or higher and 25.0 mPa·s or lower, particularly preferably 5.0 mPa·s or higher and 20.0 mPa·s or lower, at 25° C.

If the viscosity of the resin forming composition is 1.0 mPa·s or higher and 30.0 mPa·s or lower, good dischargibility can be obtained even when applying the resin forming composition to an inkjet method. Herein, the viscosity can be measured using e.g. a viscometer (apparatus name: RE-550L, manufactured by TOM SANGYO CO., LTD.) or the like.

<Resin Structure Layer Forming Process>

In the resin structure layer forming process, the polymerizable compound is polymerized in the applied resin forming composition to form a porous resin layer on the substrate. Specifically, for example, by irradiating the resin forming composition with an active energy ray, a polymerizable compound is polymerizable in the applied resin forming composition to form a porous resin layer on the substrate.

The following description explains a reason why it is preferable to form the porous resin layer on the substrate through the resin forming composition applying process and the resin structure layer forming process in the present disclosure.

In general, examples of the method for forming the porous resin layer on the substrate may include a method in which a substrate and a porous resin layer are separately prepared and bonded by a process involving high-temperature heating (hot press or the like). However, this process has a problem that low heat-resistant materials cannot be used because the substrate is deformed due to high-temperature heating, and therefore the process is limited to a combination of a substrate made of a high heat-resistant material and a porous resin.

In contrast, in the present disclosure, the porous resin layer is formed on the substrate through the resin forming composition applying process and the resin structure layer forming process that do not involve high-temperature heating, and therefore even a substrate having low heat resistance (in other words, substrate that is easily deformed by heated) can be used, and a range of options for the substrate is widened.

The active energy ray is not particularly limited as long as the active energy ray can impart energy necessary for proceeding the polymerization reaction of the polymerizable compound. Examples of the active energy ray may include ultraviolet ray, electron ray, α-ray, β-ray, γ-ray, and X-ray. Above all, ultraviolet ray is preferable. Particularly when a high-energy light source is used, the polymerization reaction can proceed without using any polymerization initiator.

Regarding the irradiation intensity of the light source that emits the active energy ray (particularly ultraviolet ray), if the irradiation intensity is too strong, the polymerization progresses rapidly before sufficient phase separation occurs, resulting in a tendency that a porous structure is hard to form. If the irradiation intensity is too weak, the phase separation may progress on a microscale or larger, and porosity unevenness and coarsening are more likely to occur. Also, an irradiation time tends to increase, resulting in lower productivity. Thus, the irradiation intensity is preferably 10 mW/cm² or higher and 1 W/cm² or lower, more preferably 30 mW/cm² or higher and 300 mW/cm² or lower.

—Porous Resin—

A film thickness of the porous resin layer is not particularly limited. In view of curing uniformity during polymerization, the film thickness is preferably 0.01 μm or larger and 500 μm or smaller, more preferably 0.01 μm or larger and 100 μm or smaller, even more preferably 1 μm or larger and 50 μm or smaller, and particularly preferably 10 μm or larger and 20 μm or smaller. When the film thickness is 0.01 μm or larger, a surface area of a resultant porous resin is increased, and the function of the porous resin can be sufficiently exerted. When the film thickness is 500 μm or smaller, light or heat used for the polymerization is suppressed from becoming non-uniform in the film thickness direction, and the resultant porous resin is uniform in the film thickness direction.

A shape of the porous resin is not particularly limited. In view of securing good permeability of gases and the like, it is preferable that the porous resin has a co-continuous structure (also referred to as monolith structure) in which a plurality of pores are continuously connected to each other. In other words, preferably, the porous resin has numerous pores and has a pore continuity in which each one of the pores is communicated with surrounding pores, and the pores spread three-dimensionally.

One physical property obtained by the co-continuous structure is air permeability. The air permeability of the porous resin can be measured in accordance with Japanese Industrial Standards (JIS) P8117. The air permeability is preferably 500 seconds/100 mL or lower, more preferably 300 seconds/100 mL or lower.

In this case, the air permeability can be measured using a Gurley densometer (manufactured by TOYO SEKI CO., LTD.) or the like.

The pores of the porous resin may have various cross-sectional shapes such as a substantially circular shape, a substantially elliptical shape, and a substantially polygonal shape, as well as various sizes. Herein, the size of the pore refers to a length of the longest part in the cross-sectional shape of the pore. The size of the pore can be determined from a cross-sectional image taken with a scanning electron microscope (SEM). The size of the pores of the porous resin is not particularly limited. In view of permeability of gases and the like, the size of the pores is preferably 0.01 μm or larger and 1 μm or smaller. In addition, the porosity of the porous resin is preferably 30% or higher, more preferably 60% or higher. A method for adjusting the pore size and the porosity of the porous resin to be within the aforementioned ranges is not particularly limited. Examples of the method may include a method in which the content of the polymerizable compound in the resin forming composition is adjusted to be within the aforementioned ranges, a method in which the content of the porogen in the resin forming composition is adjusted to be within the aforementioned ranges, and a method in which irradiation conditions of the active energy ray are adjusted. The porosity can be determined by a process in which the prepared resin is filled with an unsaturated fatty acid (commercial butter) and subjected to osmium staining, then the internal cross-sectional structure is cut out using a focused ion beam (FIB), and a porosity in the resin is measured using a scanning electron microscope (SEM).

<Solvent Removing Process>

In the solvent removing process, the solvent is removed from the porous resin after the resin structure layer forming process, and specifically, the solvent derived from the resin forming composition contained in the pores of the porous resin layer, and the like is removed. The method for removing the solvent is not particularly limited, and exemplified by a method for removing the solvent from the porous resin by heating. This method is preferable because removal of the solvent is enhanced by heating under reduced pressure, and the solvent can be prevented from remaining in the porous resin.

<Conductor Forming Composition Applying Process>

In the conductor forming composition applying process, the conductor forming composition containing at least one selected from metal oxide particles and metal particles is applied on the porous resin layer, after the resin structure layer forming process, preferably after the solvent removing process. Preferably, the applied conductor forming composition forms a conductor precursor containing components (e.g. at least one selected from metal oxide particles and metal particles described later, or the like) of the conductor forming composition, on the porous resin layer. Preferably, the applied conductor forming composition partially permeates into the porous resin layer to form a mixed region precursor where components (e.g. at least one selected from metal oxide particles and metal particles described later, and the like) of the conductor forming composition are contained within the pores of the porous resin layer, in the permeation region. When the shape of the porous resin layer includes a co-continuous structure in which the plurality of pores are continuously connected to each other as described above, the penetration of the applied conductor forming composition into the porous resin layer can be facilitated.

The method for applying the conductor forming composition is not particularly limited. Examples of the method may include various printing methods such as an inkjet printing method, a screen printing method, a gravure printing method, and an offset printing method. Above all, an inkjet printing method is preferable from the viewpoint that fine patterns can be printed with no contact by discharging the conductor forming composition to the porous resin layer. Since the printing is possible with no contact, deformation of the porous resin layer to be applied is suppressed, and therefore cracks on the conductor disposed on the porous resin layer are suppressed, and, as a result, the conductivity of the conductor and the adhesiveness of the conductor to the porous resin layer can be improved.

—Conductor forming Composition—

The conductor forming composition contains at least one selected from metal oxide particles and metal particles, and, as necessary, may contain a reducing agent, a resin, a dispersant, or the like.

—Metal Oxide Particle and Metal Particle—

At least one selected from reduced metal oxide particles and metal particles is sintered to form a conductor or a material contained within pores in a mixed region described later.

Examples of the material constituting the metal particles may include gold, silver, copper, silver-coated copper, aluminum, nickel, and cobalt. From the viewpoint of improving conductivity, silver, copper, and silver-coated copper are preferable. One of these materials may be selected, or a plurality of these materials in any ratio may be used in combination.

The material constituting the metal oxide particles can be exemplified by an oxide of a material constituting the aforementioned metal particles. From the viewpoint of improving conductivity, silver oxide and copper oxide are preferable. One of these materials may be selected, or a plurality of these materials in any ratio may be used in combination.

The shapes of the metal oxide particles and the metal particles are not particularly limited. A spherical, flat (platelike), or irregularly shaped material can be used.

Excessively small particle diameters of the metal oxide particles and the metal particles are disadvantageous from the viewpoint of productivity, because, depending on a desired printing accuracy, dispersibility of the particles in the conductor forming composition is hardly secured, and an amount of a protective colloid used for preventing agglomeration must be increased, and a ratio of metals in the solid content of the conductor forming composition is hardly increased. Excessively large particle diameters cause problems that fine patterns are hardly printed, particles hardly come into contact with each other, resulting in difficulty of sintering. Thus, the particle diameters of the metal oxide particles and the metal particles are preferably 5 nm or larger and 10 μm or smaller, more preferably 10 nm or larger and 5 μm or smaller. Note that the particle diameters of the metal oxide particles and the metal particles refer to an average particle diameter D50 (median diameter) based on the number of particles, which can be measured by a laser diffraction scattering method or a dynamic light scattering method.

—Reducing Agent—

When using the metal oxide particles, it is preferable that the conductor forming composition contains a reducing agent. Since the conductor forming composition contains the reducing agent, reduced products of the metal oxide particles are produced. The reduced products are sintered to form a conductor or a material (metal) contained within the pores of the mixed region described later.

Examples of the reducing agent may include an alcohol compound such as methanol, ethanol, isopropyl alcohol, butanol, cyclohexanol, and terpineol; a polyhydric alcohol such as ethylene glycol, propylene glycol, and glycerol; a carboxylic acid such as formic acid, acetic acid, oxalic acid, and succinic acid; a carbonyl compound such as acetone, methyl ethyl ketone, cyclohexane, benzaldehyde, and octylaldehyde; an ester compound such as ethyl acetate, butyl acetate, and phenyl acetate; a hydrocarbon compound such as hexane, octane, toluene, naphthalene, and decalin. Above all, a polyhydric alcohol such as ethylene glycol, propylene glycol, and glycerin; and a carboxylic acid such as formic acid, acetic acid, and oxalic acid are preferable, considering an efficiency of the reducing agent.

—Resin—The conductor forming composition preferably contains a resin having a binder function, and more preferably further contains a resin that also serves as a reducing agent in addition to the binder function.

Examples of the resin that has the binder function and also serves as a reducing agent may include a poly-N-vinyl compound such as polyvinylpyrrolidone and polyvinylcaprolactone; a polyalkylene glycol compound such as polyethylene glycol, polypropylene glycol, and poly-tetrahydrofuran (THF); a polyurethane; a cellulose compound and a derivative thereof; a thermoplastic or thermosetting resin such as an epoxy compound, a polyester compound, a chlorinated polyolefin, and a polyacrylic compound. Above all, in consideration of the binder function, polyvinylpyrrolidone is preferable, and, in consideration of the reducing function, polyethylene glycol and polypropylene glycol, and a polyurethane compound are preferable. Note that polyethylene glycol and polypropylene glycol are classified into polyhydric alcohols and have suitable characteristics particularly as a reducing agent.

—Dispersion Medium—

Preferably, the conductor forming composition contains at least one dispersion medium selected from metal oxide particles and metal particles. As the dispersion medium, a known liquid component can be used.

—Method for Producing Conductor Forming Composition—

Preferably, the conductor forming composition is prepared through a process in which at least one selected from metal oxide particles and metal particles is dispersed in a dispersion medium, a process in which other components are further dissolved or dispersed, a process in which the mixture is stirred to form a uniform dispersion liquid, and the like.

—Physical Properties of Conductor Forming Composition—

From the viewpoint of operability in applying the conductor forming composition, the viscosity of the conductor forming composition is preferably 1.0 mPa·s or higher and 150.0 mPa·s or lower, more preferably 1.0 mPa·s or higher and 30.0 mPa·s or lower, even more preferably 1.0 mPa·s or higher and 25.0 mPa·s or lower, particularly preferably 5.0 mPa·s or higher and 20.0 mPa·s or lower, at 25° C.

If the viscosity of the conductor forming composition is 1.0 mPa·s or higher and 30.0 mPa·s or lower, good dischargibility can be obtained even when applying the conductor forming composition to an inkjet method. Herein, the viscosity can be measured using e.g. a viscometer (apparatus name: RE-550L, manufactured by TOM SANGYO CO., LTD.) or the like.

<Conductor Forming Process>

In the conductor forming process, after the conductor forming composition applying process, at least one selected from metal oxide particles and metal particles is selectively caused to generate heat to form a conductor including at least one sintered compact selected from the reduced metal oxide particles and the metal particles on the porous resin layer. Specifically, in the conductor forming composition applying process, at least one selected from metal oxide particles and metal particles contained in a conductor precursor formed on the porous resin layer is selectively caused to generate heat to form a conductor including at least one sintered compact selected from the reduced metal oxide particles and the metal particles on the porous resin layer.

Also, in the conductor forming process, preferably at least one selected from metal oxide particles and metal particles is selectively caused to generate heat at the same time as the formation of the conductor to produce a mixed region having at least one sintered compact selected from the reduced metal oxide particles and the metal particles within the pores of the porous resin layer. Specifically, in the conductor forming composition applying process, it is preferable that at least one selected from metal oxide particles and metal particles contained in the mixed region precursor formed in the porous resin layer is selectively caused to generate heat to produce a mixed region having at least one sintered compact selected from the reduced metal oxide particles and the metal particles within the pores of the porous resin layer.

Since the mixed region precursor is formed when the conductor forming composition applied to form the conductor precursor permeates into the porous resin layer, the material of the components contained in the pores of the mixed region formed through the conductor forming process is the same as the material constituting the conductor, the components contained within the pores of the mixed region and the conductor are continuous, and the conductor and the mixed region are adjacent to each other.

Thereby, the adhesiveness of the conductor to the porous resin layer can be improved. The shape of the porous resin has a co-continuous structure with a plurality of pores continuously connected to each other as described above, and when the components contained within the plurality of pores are continuous with each other, the adhesiveness of the conductor to the porous resin layer is further improved.

The mixed region in the porous resin layer only needs to be distributed such that the adhesiveness of the conductor to the porous resin layer is improved by the continuity between the components contained within the pores of the mixed region and the conductor, and the mixed region need not be present over the entire porous resin layer. Specifically, the adhesiveness is improved as long as the mixed region is present in a small area from an interface between the conductor and the mixed region in the film thickness direction of the porous resin layer. More specifically, for example, a ratio (X/Y) of the length (X) in the film thickness direction in the mixed region to the length (Y) in the film thickness direction in the region excluding the mixed region of the porous resin layer is preferably 0.5/99.5 or larger and 1.0/99.0 or smaller.

The method for selectively causing at least one selected from metal oxide particles and metal particles to generate heat can be exemplified by an internal heating method. In the internal heating method according to the present disclosure, at least one selected from metal oxide particles and metal particles is caused to generate heat but the substrate and the porous resin layer are not caused. Since the substrate and the porous resin layer do not generate heat, deformation of the substrate and the porous resin layer are suppressed, and thereby, cracks on the conductor disposed on the porous resin layer are suppressed, and, as a result, the conductivity of the conductor and the adhesiveness of the conductor to the porous resin layer can be improved. In addition, since the substrate and the porous resin layer do not generate heat, at least one selected from metal oxide particles and metal particles can be sufficiently heated to improve the conductivity of the formed conductor. Furthermore, since the substrate does not generate heat, even a substrate having low heat resistance (in other words, substrate that is easily deformed when heated) can be used, and a range of options for the substrate is widened. In the present disclosure, the term “heat generation” means that the temperature of the object itself rises, and does not include a means that the temperature of the object rises due to the rise in temperature of matters surrounding the object.

From the viewpoint of improving productivity, preferable examples of the internal heating method may include a pulsed-light radiation method and a microwave irradiation method, and above all, a pulsed-light irradiation method is more preferable.

A pulsed light in the pulsed-light irradiation refers to a short-time exposure light with a light irradiation period (irradiation time) of several microseconds to several tens of milliseconds. When light irradiation is repeated multiple times, the light irradiation includes a period without light irradiation (off) between a first light irradiation period (on) and a second light irradiation period (on). Specifically, an irradiation time of one pulse light irradiation (on) is preferably in a range of about 20 microseconds to about 10 milliseconds. If the irradiation time is longer than 20 microseconds, sintering is enhanced to improve the conductivity of the formed conductor. In addition, if the irradiation time is shorter than 10 microseconds, an influence of photodegradation is suppressed. The light intensity may also vary within one light exposure period (on). The wavelength of the irradiation light is preferably 200 nm to 3000 nm. In addition, a light source for emitting a pulsed light can be exemplified by a light source equipped with a flash lamp such as a xenon flash lamp.

The microwave in the microwave irradiation refers to an electromagnetic wave having a wavelength range of 1 m to 1 mm (frequency: 300 MHz to 300 GHz).

When at least one selected from metal oxide particles and metal particles is selectively caused to generate heat by irradiation with a pulsed light or a microwave, these particles rapidly generate heat, organic components such as the reducing agent around the particles are decomposed to generate a gas, thus voids are generated within the conductor due to the gas, and thereby the conductivity of the conductor and the adhesiveness of the conductor to the porous resin layer may be decreased. In contrast, since the conductor according to the present disclosure is formed on the porous resin layer, the generated gas is released to the outside through the pores inside the porous resin layer, so that decrease in the conductivity of the conductor and the adhesiveness of the conductor to the porous resin layer can be suppressed. At this time, the generated gas can be more easily released to the outside because the shape of the porous resin has a co-continuous structure with the plurality of pores continuously connected to each other, as described above.

«Conductor Producing Apparatus»

The conductor producing apparatus according to this embodiment includes: a resin forming composition applying device configured to apply a resin forming composition containing a polymerizable compound and a solvent on a substrate; a porous resin layer forming device configured to polymerize the polymerizable compound in the applied resin forming composition to form a porous resin layer on the substrate; and a conductor forming composition applying device configured to apply a conductor forming composition containing at least one selected from metal oxide particles and metal particles on the porous resin layer.

Also, the conductor producing apparatus according to this embodiment may have other devices, as necessary. For example, the conductor producing apparatus may include a solvent removing device configured to remove the solvent from the porous resin layer, after the formation of the porous resin layer using the porous resin layer forming device and before the application of the conductor forming composition using the conductor forming composition applying device; and a conductor forming device configured to selectively cause at least one selected from metal oxide particles and metal particles to generate heat to form a conductor including at least one sintered compact selected from the reduced metal oxide particles and the metal particles on the porous resin layer, after the application of the conductor forming composition using the conductor forming composition applying device.

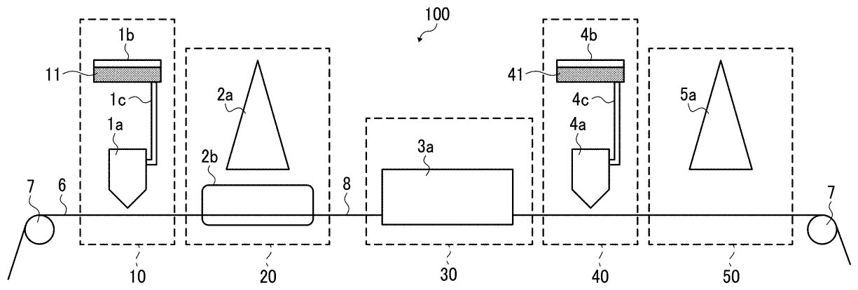

The conductor producing apparatus will be explained in detail with reference to FIG. 1. FIG. 1 is a schematic diagram illustrating an example of a conductor producing apparatus.

A conductor producing apparatus 100 is configured to produce a conductor using the aforementioned resin forming composition and conductor forming composition. The conductor producing apparatus 100 includes a resin forming composition applying process part 10 configured to perform a process in which the resin forming composition is applied on a substrate 6 to form a resin forming composition layer; a resin structure layer forming process part 20 configured to perform a process in which a polymerization initiator of the resin forming composition layer is activated to obtain a porous resin layer 8 formed on the substrate 6 by polymerization of a polymerizable compound; a solvent removing process part 30 configured to perform a process in which the porous resin layer 8 is heated to remove a solvent; a conductor forming composition applying process part 40 configured to perform a process in which the conductor forming composition is applied on the porous resin layer 8 to form a conductor precursor on the porous resin layer 8 and a mixed region precursor within the porous resin layer 8; and a conductor forming process part 50 configured to perform a process in which at least one selected from metal oxide particles and metal particles contained in the conductor forming composition is selectively caused to generate heat to form the conductor on the porous resin layer 8 and the mixed region within the porous resin layer 8. The conductor producing apparatus 100 includes a plurality of conveyers 7 configured to convey the substrate 6, and the conveyers 7 convey the substrate 6 through the resin forming composition applying process part 10, the resin structure layer forming process part 20, the solvent removing process part 30, the conductor forming composition applying process part 40, and the conductor forming process part 50 in this order at a preset speed.

<Resin Forming Composition Applying Process Part>

As illustrated in FIG. 1, the resin forming composition applying process part 10 includes a printing device 1a that is an example of the resin forming composition applying device configured to apply the resin forming composition on the substrate 6, an accommodating container 1b accommodating a resin forming composition 11, and a supply tube 1c configured to supply the resin forming composition stored in the accommodating container 1b to the printing device 1a.

The accommodating container 1b accommodates the resin forming composition 11, and the resin forming composition applying process part 10 discharges the resin forming composition 11 from the printing device 1a to apply the resin forming composition 11 on the substrate 6 to form the resin forming composition layer in a thin film shape. The accommodating container 1b may be either integrated with the conductor producing apparatus 100 or detachable from the conductor producing apparatus 100. Also, the accommodating container 1b may be used for adding the resin forming composition to the accommodating container integrated with or detachable from the conductor producing apparatus 100.

The printing device 1a is not particularly limited as long as the printing device 1a can apply the resin forming composition 11. For example, any printing device can be used depending on various printing methods such as a spin coating method, a casting method, a micro-gravure coating method, a gravure coating method, a bar coating method, a roll coating method, a wire bar coating method, a dip coating method, a slit coating method, a capillary coating method, a spray coating method, a nozzle coating method, a gravure printing method, a screen printing method, a flexographic printing method, an offset printing method, a reverse printing method, and an inkjet printing method.

The accommodating container 1b and the supply tube 1c can be arbitrarily selected as long as the accommodating container 1b and the supply tube 1c can stably store and supply the resin forming composition 11. Preferably, materials constituting the accommodating container 1b and the supply tube 1c have a light-shielding property in relatively short wavelength regions such as ultraviolet regions and visible light regions. Thereby, the resin forming composition 11 is prevented from starting a polymerization by external light.

<Resin Structure Layer Forming Process Part>

As illustrated in FIG. 1, the resin structure layer forming process part 20 includes: an irradiating device 2a that is an example of the porous resin layer forming device configured to polymerize a polymerizable compound by emitting active energy rays such as heat and light to the resin forming composition; a polymerization-inactive gas circulating device 2b that circulates a polymerization-inactive gas. The irradiating device 2a irradiates the resin forming composition layer formed by the resin forming composition applying process part 10 with light in the presence of the polymerization-inactive gas to form the porous resin layer.

The irradiating device 2a is not particularly limited as long as the irradiating device 2a is appropriately selected depending on an absorption wavelength of a photopolymerization initiator contained in the resin forming composition layer and is capable of initiating and proceeding the polymerization of the polymerizable compound contained in the resin forming composition layer. Examples of the irradiating device 2a may include ultraviolet light sources such as high-pressure mercury lamp, metal halide lamp, hot cathode tube, cold cathode tube, and light emitting diode (LED). However, since light having a shorter wavelength generally tends to reach a deeper portion, it is preferable that the light source is selected depending on the thickness of the porous resin layer to be formed.

The polymerization-inactive gas circulating device 2b plays a role of lowering the concentration of polymerization-active oxygen in the atmosphere to proceed a polymerization reaction of the polymerizable compound present near the surface of the resin forming composition layer without any inhibition. Thus, the polymerization-inactive gas used is not particularly limited as long as the polymerization-inactive gas satisfies the aforementioned functions. Examples of the polymerization-inactive gas may include nitrogen, carbon dioxide, and argon.

The flow rate of the polymerization-inactive gas is determined in consideration of an efficient inhibition reduction effect. The 02 concentration is preferably lower than 20% (an environment where the oxygen concentration is lower than that of the atmosphere), more preferably 0% or higher and 15% or lower, even more preferably 0% or higher and 5% or lower.

It is preferable that the polymerization-inactive gas circulating device 2b is equipped with a temperature controlling device capable of controlling the temperature for achieving stable polymerization proceeding conditions.

<Solvent Removing Process Part>

As illustrated in FIG. 1, the solvent removing process part 30 includes a heating device 3a as an example of the solvent removing device, where a solvent remaining in the porous resin layer 8 formed in the resin structure layer forming process part 20 is removed by heating and drying with the heating device 3a. In the solvent removing process part 30, the solvent removing process may be performed under reduced pressure.

In the solvent removing process part 30, the photopolymerization initiator remaining in the porous resin layer 8 may be removed by heating and drying with the heating device 3a.

The heating device 3a is not particularly limited as long as the heating device 3a satisfies the aforementioned functions. Examples of the heating device 3a may include an infrared (IR) heater and a hot air heater.

The heating temperature and time can be appropriately selected depending on the boiling point of the solvent contained in the porous resin layer 8, or the thickness of the formed film.

<Conductor Forming Composition Applying Process Part>

As illustrated in FIG. 1, the conductor forming composition applying process part 40 includes a printing device 4a as an example of the conductor forming composition applying device configured to apply the conductor forming composition on the porous resin layer 8, an accommodating container 4b accommodating a conductor forming composition 41, and a supply tube 4c configured to supply the conductor forming composition stored in the accommodating container 4b to the printing device 4a.

The accommodating container 4b accommodates the conductor forming composition 41, and the conductor forming composition applying process part 40 discharges the conductor forming composition 41 from the printing device 4a to apply the conductor forming composition 41 on the porous resin layer 8 to form the conductor precursor on the porous resin layer 8 and the mixed region precursor in the porous resin layer 8. The accommodating container 4b may be either integrated with the conductor producing apparatus 100 or detachable from the conductor producing apparatus 100. Also, the accommodating container 4b may be used for adding the resin forming composition to the accommodating container integrated with or detachable from the conductor producing apparatus 100.

The printing device 4a is not particularly limited as long as the conductor forming composition 41 can be applied on the printing device 4a. For example, any printing device can be used according to various printing methods such as an inkjet printing method, a screen printing method, a gravure printing method, and an offset printing method.

The accommodating container 4b and the supply tube 4c can be arbitrarily selected as long as the accommodating container 4b and the supply tube 4c can stably store and supply the conductor forming composition 41.

<Conductor Forming Process Part>

As illustrated in FIG. 1, the conductor forming process part 50 includes an irradiating device 5a as an example of the conductor forming device configured to selectively cause at least one selected from metal oxide particles and metal particles contained in the conductor forming composition to generate heat to form the conductor on the porous resin layer 8 and the mixed region in the porous resin layer 8. The irradiating device 5a causes at least one selected from the metal oxide particles and the metal particles contained in the conductor forming composition to generate heat by the internal heating method to form, on the porous resin layer, the conductor containing at least one sintered compact selected from the reduced metal oxide particles and the metal particles, and the mixed region having at least one sintered compact selected from the reduced metal oxide particles and the metal particles within the pores of the porous resin layer.

The irradiating device 5a is not particularly limited as long as the irradiating device 5a can cause at least one selected from the metal oxide particles and the metal particles contained in the conductor forming composition to generate heat by an internal heating method. Examples of the irradiating device 5a may include a device capable of emitting pulsed lights and a device capable of emitting microwaves, as described above.

«Structure»

The structure according to this embodiment has a substrate, a porous resin layer formed on the substrate, and a conductor formed on the porous resin layer. Also, the structure according to this embodiment may have other structures as necessary. The details of the structures and constituent materials of the substrate, the porous resin layer, and the conductor are as described above, and therefore omitted.

### EXAMPLES

Examples of the present invention will be explained below, but the present invention is not limited to Examples at all.

### Example 1

—Resin Forming Composition Applying Process—

A resin forming composition adjusted as described below was applied on a substrate (PET film, manufactured by Toray Industries, Inc.) using a dispenser. The substrate was subjected to a differential scanning calorimetry (DSC), and as a result, an endothermic peak appeared at 300° C. or lower.

(Preparation of Resin Forming Composition)

A resin forming composition was prepared by mixing materials in a proportion described below. For the prepared resin forming composition, a light transmittance at a wavelength of 550 nm was measured while stirring in accordance with the aforementioned method, and as a result, the light transmittance was proved to be 30% or higher (the polymerizable compound was compatible with the solvent). For a haze measuring element prepared by using the prepared resin forming composition, a rate of increase in a haze value was measured in accordance with the aforementioned method, and as a result, the rate was proved to be 1.0% or higher (the polymer produced in the polymerizing process of the polymerizable compound became incompatible with the solvent).
Tricyclodecanedimethanol diacrylate (DAICEL-ALLNEX LTD.): 49.0% by mass
Dipropylene glycol monomethyl ether (Kanto Chemical Industry Co., Ltd.): 50.0% by mass
IRGACURE 184 (manufactured by BASF SE): 1.0% by mass

—Resin Structure Layer Forming Process—

Subsequently, the resin forming composition was applied to the substrate, and after one minute, the substrate was irradiated with ultraviolet ray under nitrogen atmosphere to form a porous resin layer on the substrate. UV irradiation conditions are described below.
Light source: UV-LED (trade name: FJ800, manufactured by Phoseon Technology).
Light source wavelength: 365 nm
Irradiation intensity: 30 mW/cm²
Irradiation time: 20 s

—Solvent Removing Process—

Subsequently, the substrate was heated on a hot plate at 120° C. for 1 minute, so that the solvent derived from the resin forming composition was removed from the porous resin layer by drying.

The obtained porous resin layer was observed by SEM, and as a result, a co-continuous structure was observed, in which a plurality of pores having a diameter of about 0.1 to 1 μm were continuously connected to each other. The substrate and the porous resin layer were subjected to a differential scanning calorimetry (DSC), and as a result, the temperature at the exothermic or endothermic peak on the substrate was lower than that of the endothermic peak on the porous resin layer.

—Conductor Forming Composition Applying Process—

Subsequently, a conductor forming composition (copper oxide ink (ICI-003), manufactured by NovaCentrix) was discharged onto the formed porous resin layer using an inkjet printing device (IJ-DESK, manufactured by Genesis Co., Ltd.). Subsequently, the substrate was heated on a hot plate at 100° C. for 10 minute, so that the solvent derived from the conductor forming composition was removed by drying.

—Conductor Forming Process—

Subsequently, the substrate was irradiated with light with an irradiation energy of 3 J/cm² using a photo-sintering apparatus (Sinteron 2000, manufactured by XENON Corporation) to prepare a structure as a circuit board in which the porous resin layer and the conductor are sequentially laminated on the substrate.

As a result of observation of the structure by SEM, the porous resin layer has a mixed region containing the same material as of the conductor within the pores, and the components and the conductor contained within the pores in the mixed region were continuous. The thickness of the conductor was measured with a probe type step profiler (α-step), and as a result, the conductor had a thickness of 1 μm. The mixed region had a thickness of 100 nm.

### Example 2

In Example 1, a structure as a circuit board was prepared in the same manner as in Example 1 except that a different substrate (PEN film, manufactured by TEIJIN LIMITED) was used instead of the substrate (PET film, manufactured by Toray Industries, Inc.) in Example 1.

The substrate was subjected to a differential scanning calorimetry (DSC), and as a result, an endothermic peak appeared at 300° C. or lower.

### Example 3

A structure as a circuit board was prepared in the same manner as in Example 1 except that a different substrate (polycarbonate sheet, manufactured by MITSUBISHI GAS CHEMICAL COMPANY, INC.) was used instead of the substrate (PET film, manufactured by Toray Industries, Inc.) in Example 1.

The substrate was subjected to a differential scanning calorimetry (DSC), and as a result, an exothermic peak appeared at 300° C. or lower.

### Comparative Example 1

A structure as a circuit board was prepared in the same manner as in Example 1 except that the resin forming composition applying process, the resin structure layer forming process, and the solvent removing process were not performed and the conductor forming composition was discharged onto a substrate (PET film, Toray Industries, Inc.) in the conductor forming composition applying process in Example 1.

### Comparative Example 2

In Example 1, a structure as a circuit board was prepared in the same manner as in Example 1 except that a resin forming composition described below was used instead of the aforementioned resin forming composition.

The resin formed from the following resin forming composition was observed by SEM, and as a result, a resin layer having no porous structure was observed.

(Preparation of Resin Forming Composition)

A resin forming composition was prepared by mixing materials in a proportion described below. For the prepared resin forming composition, a light transmittance at a wavelength of 550 nm was measured while stirring in accordance with the aforementioned method, and as a result, the light transmittance was proved to be 30% or higher (the polymerizable compound was compatible with the solvent). For a haze measuring element prepared by using the prepared resin forming composition, a rate of increase in a haze value was measured in accordance with the aforementioned method, and as a result, the rate was proved to be lower than 1.0% (the polymer produced in the polymerizing process of the polymerizable compound was compatible with the solvent).
Tricyclodecanedimethanol diacrylate (DAICEL-ALLNEX LTD.): 49.0% by mass
Cyclohexanone (manufactured by Kanto Chemical Industry Co., Ltd.): 50.0% by mass
IRGACURE 184 (manufactured by BASF SE): 1.0% by mass

### Comparative Example 3

A structure as a circuit board was prepared in the same manner as in Comparative Example 1 except that a different substrate (porous PET film (IJ-220), manufactured by NovaCentrix) was used instead of the substrate (PET film, manufactured by Toray Industries, Inc.) in Comparative Example 1.

The substrate was subjected to a differential scanning calorimetry (DSC), and as a result, an endothermic peak appeared at 300° C. or lower.

### Comparative Example 4

A structure as a circuit board was prepared in the same manner as in Comparative Example 1 except that a different substrate (non-communicated porous polycarbonate film (ISOPORE VCTP14250, manufactured by Merck KGaA) was used instead of the substrate (PET film, manufactured by Toray Industries, Inc.) in Comparative Example 1.

The substrate was subjected to a differential scanning calorimetry (DSC), and as a result, an exothermic peak appeared at 300° C. or lower.

Subsequently, for each of the produced structures, the conductivity of the conductor and the adhesiveness of the conductor to adjacent members (the porous resin layer and the like) were evaluated in accordance with the following methods. Table 1 presents the evaluation results.

[Conductivity]

Based on the thickness of the conductor, a volume resistivity was measured by a four-terminal method using a four-probe resistivity meter (low-resistivity meter, Loresta, manufactured by Nittoseiko Analytech Co., Ltd.) to evaluate the conductivity in accordance with the following evaluation criteria.

(Evaluation Criteria)

A: Volume resistivity is lower than 1.0×10⁻⁴ Ω·cm.

B: Volume resistivity is 1.0×10⁻⁴ Ω·cm or higher and lower than 1.0×10⁻² Ω·cm.

C: Volume resistivity is 1.0×10⁻² Ω·cm or higher.

[Adhesiveness]

A tape peel test was performed, in which an adhesive tape bonded onto the conductor was peeled off. A state of the surface of the conductor after the test was observed under a microscope and evaluated in accordance with the following evaluation criteria.

(Evaluation Criteria)

A: No cracks are observed

B: Cracks are observed without defects

C: Defects are observed

TABLE 1

| | | Conductivity | Adhesiveness |
|---|---|---|---|
| Examples | 1 | A | A |
| | 2 | A | A |
| | 3 | A | A |
| Comparative | 1 | C | C |
| Examples | 2 | C | C |
| | 3 | B | B |
| | 4 | B | B |

The evaluation results of Examples 1 to 3 indicated that the structures produced by the producing method according to embodiments of the present invention were excellent in conductivity and adhesiveness.

On the other hand, the evaluation results of Comparative Example 1 indicated that, when the conductor was directly formed on the substrate, the structure was poor in conductivity and adhesiveness.

The evaluation results of Comparative Example 2 indicated that the structure was poor in conductivity and adhesiveness because the resin formed on the substrate had no porous structure.

The evaluation results of Comparative Example 3 indicated that, when the conductor was directly formed on the substrate having the porous structure inferior in heat resistance, the structure was poor in conductivity and adhesiveness.

The evaluation results of Comparative Example 4 indicated that, when the conductor was directly formed on the substrate having the non-communicated porous structure inferior in heat resistance, the structure was poor in conductivity and adhesiveness.

Numerous additional modifications and variations are possible in light of the above teachings. It is therefore to be understood that, within the scope of the above teachings, the present disclosure may be practiced otherwise than as specifically described herein. With some embodiments having thus been described, it will be obvious that the same may be varied in many ways. Such variations are not to be regarded as a departure from the scope of the present disclosure and appended claims, and all such modifications are intended to be included within the scope of the present disclosure and appended claims.

1. A method for producing a conductor, the method comprising:
applying a resin forming composition containing a polymerizable compound and a solvent on a substrate;
polymerizing the polymerizable compound in the applied resin forming composition to form a resin structure that is porous on the substrate; and
applying a conductor forming composition containing at least one selected from the group consisting of metal oxide particles and metal particles on the resin structure.

2. The method according to claim 1, further comprising:
selectively causing at least one selected from the group consisting of the metal oxide particles and the metal particles to generate heat to form the conductor on the resin structure, the conductor comprising at least one sintered compact selected from the group consisting of reduced products of the metal oxide particles and the metal particles.

3. The method according to claim 2, further comprising:
selectively causing at least one selected from the group consisting of the metal oxide particles and the metal particles to generate heat to form a mixed region having at least one sintered compact selected from the group consisting of reduced products of the metal oxide particles and the metal particles within pores of the resin structure.

4. The method according to claim 2, wherein the heat is generated by irradiation with a pulsed light or a microwave.

5. The method according to claim 1, wherein
the polymerizable compound is compatible with the solvent, and
the resin structure is formed as a polymer that is produced during the polymerizing the polymerizable compound becomes incompatible with the solvent.

6. The method according to claim 1, wherein the applying the conductor forming composition includes discharging the conductor forming composition.

7. The method according to claim 1,
wherein the applying the conductor forming composition includes discharging the conductor forming composition by an inkjet method.

8. The method according to claim 1, wherein a differential scanning calorimetry (DSC) on the substrate and the resin structure indicates that a temperature at an exothermic peak or an endothermic peak on the substrate is lower than a temperature at an endothermic peak on the resin structure.

9. The method according to claim 1, wherein a differential scanning calorimetry (DSC) on the substrate indicates that an exothermic peak or an endothermic peak appears at 300° C. or lower.

10. The method according to claim 1, wherein the substrate contains at least one selected from the group consisting of polyethylene, polypropylene, polyethylene terephthalate, and polyethylene naphthalate.

11. The method according to claim 1, wherein the resin structure has a co-continuous structure in which a plurality of pores are continuously connected to each other.

12. The method according to claim 1, wherein the resin structure contains a resin having an intramolecular crosslinked structure.

13. A conductor producing apparatus, the apparatus comprising:
a resin forming composition applying device configured to apply a resin forming composition containing a polymerizable compound and a solvent on a substrate;
a resin structure forming device configured to polymerize the polymerizable compound in the applied resin forming composition to form a resin structure that is porous on the substrate; and
a conductor forming composition applying device configured to apply a conductor forming composition containing at least one selected from the group consisting of metal oxide particles and metal particles on the resin structure.

14. A structure comprising:
a substrate;
a resin structure on the substrate, the resin structure being porous; and
a conductor on the resin structure,
the resin structure comprising an acrylic resin, and
the resin structure having a mixed region containing a material same as a material of the conductor within pores.
